(19) United States
(12) Patent Application Publication
(10) Pub. No.: US 2024/0220743 A1
(43) Pub. Date: Jul. 4, 2024

(54) HYBRID STRUCTURE FOR COMPUTING-IN-MEMORY APPLICATIONS AND COMPUTING METHOD THEREOF

(71) Applicant: NATIONAL TSING HUA UNIVERSITY, HSINCHU (TW)

(72) Inventors: Meng-Fan CHANG, Hsinchu (TW); Ping-Chun WU, Hsinchu (TW); Jin-Sheng REN, Hsinchu (TW); Li-Yang HONG, Hsinchu (TW); Ho-Yu CHEN, Hsinchu (TW)

(21) Appl. No.: 18/148,436

(22) Filed: Dec. 30, 2022

(51) Int. Cl. G06J 1/00

(52) U.S. Cl. CPC G06J 1/00

(57) ABSTRACT

A hybrid structure for computing-in-memory applications includes a memory cell and a digital-analog-hybrid local computing cell. The memory cell stores a weight. The digital-analog-hybrid local computing cell has a plurality of input lines, a digital output line and an analog output line. The input lines are configured to transmit a plurality of multi-bit input values. The digital-analog-hybrid local computing cell includes a digital local computing cell and a voltage local computing cell. The digital local computing cell receives the weight and is configured to generate a digital output value on the digital output line according to a higher bit of the multi-bit input values multiplied by the weight. The voltage local computing cell receives the weight and is configured to generate an analog output value on the analog output line according to a lower bit of the multi-bit input values multiplied by the weight.

### BACKGROUND

### Technical Field

The present disclosure relates to a hybrid structure for memory applications and a computing method thereof. More particularly, the present disclosure relates to a hybrid structure for computing-in-memory applications and a computing method thereof.

### Description of Related Art

Computing-in-memory (CIM) is a promising solution that can reduce the energy consumption of artificial intelligence (AI) chip multiplication and accumulation (MAC) operations. In order to increase the bandwidth and reduce the power consumption of each operation, CIM would turn on multiple word lines (WL) in a memory array to compute at the same time. The computing results will accumulate on bit lines (BL) and read out by readout circuit or digital circuit that both are the current development directions. There are two kinds of CIM macro in conventional CIM structures. One is an analog CIM (ACIM) structure, and the other is a digital CIM (DCIM) structure. However, the conventional ACIM structure may suffer from process, voltage and temperature (PVT) variation, thus reducing readout accuracy which has an effect on the application of CIM. The conventional DCIM structure has higher accuracy and more PVT tolerance than the conventional ACIM structure, but it may be restricted by operation parallelism and layout routine limitation. Accordingly, a hybrid structure for computing-in-memory applications and a computing method thereof having the features of improving high performance and maintaining high accuracy are commercially desirable.

### SUMMARY

According to one aspect of the present disclosure, a hybrid structure for computing-in-memory applications is controlled by a first word line and a second word line, and the hybrid structure for computing-in-memory applications includes at least one memory cell and at least one digital-analog-hybrid local computing cell. The at least one memory cell stores a weight. The at least one memory cell is controlled by the first word line and includes a local bit line transmitting the weight. The at least one digital-analog-hybrid local computing cell is controlled by the second word line and has a plurality of input lines, a digital output line and an analog output line. The input lines are configured to transmit a plurality of multi-bit input values. The at least one digital-analog-hybrid local computing cell includes at least one digital local computing cell and at least one voltage local computing cell. The at least one digital local computing cell is connected to the at least one memory cell. The at least one digital local computing cell receives the weight via the local bit line and is configured to generate a digital output value on the digital output line according to a higher bit of the multi-bit input values multiplied by the weight. The at least one voltage local computing cell is connected to the at least one memory cell and the at least one digital local computing cell. The at least one voltage local computing cell receives the weight via the local bit line and is configured to generate an analog output value on the analog output line according to a lower bit of the multi-bit input values multiplied by the weight.

According to another aspect of the present disclosure, a computing method of a hybrid structure for computing-in-memory applications is controlled by a first word line and a second word line, and the computing method includes performing a voltage level applying step and a digital-analog-hybrid computing step. The voltage level applying step includes applying a plurality of voltage levels to the first word line, the second word line, a plurality of input lines of at least one digital-analog-hybrid local computing cell and a weight of at least one memory cell. The digital-analog-hybrid computing step includes performing a digital computing step and an analog computing step. The digital computing step includes configuring at least one digital local computing cell of the at least one digital-analog-hybrid local computing cell to generate a digital output value on a digital output line according to a higher bit of a plurality of multi-bit input values multiplied by the weight. The analog computing step includes configuring at least one voltage local computing cell of the at least one digital-analog-hybrid local computing cell to generate an analog output value on an analog output line according to a lower bit of the multi-bit input values multiplied by the weight.

### BRIEF DESCRIPTION OF THE DRAWINGS

The present disclosure can be more fully understood by reading the following detailed description of the embodiment, with reference made to the accompanying drawings as follows:

FIG. 1 shows a schematic view of a hybrid structure for computing-in-memory applications according to a first embodiment of the present disclosure.

FIG. 2 shows a schematic view of a digital local computing cell of a digital-analog-hybrid local computing cell of FIG. 1.

FIG. 3 shows a schematic view of a voltage local computing cell of the digital-analog-hybrid local computing cell of FIG. 1.

FIG. 4A shows a schematic view of one of a plurality of place-value dependent hybrid-domain computing blocks of the hybrid structure for computing-in-memory applications of FIG. 1.

FIG. 4B shows a circuit diagram of one column structure of the one of the place-value dependent hybrid-domain computing blocks of FIG. 4A.

FIG. 5 shows a timing diagram associated with the digital local computing cell and the voltage local computing cell of FIG. 4B.

FIG. 6 shows a schematic view of weight scramble of the one of the place-value dependent hybrid-domain computing blocks of FIG. 1.

FIG. 7 shows a flow chart of a computing method of a hybrid structure for computing-in-memory applications according to a second embodiment of the present disclosure.

FIG. 8 shows a schematic view of a hybrid structure for computing-in-memory applications according to a third embodiment of the present disclosure.

FIG. 9 shows a schematic view of a word line and input driver of the hybrid structure for computing-in-memory applications of FIG. 8.

FIG. 10 shows a schematic view of a serial delay computing circuit of the word line and input driver of FIG. 9.

FIG. 11 shows a schematic view of a winner-take-all circuit of the word line and input driver of FIG. 9.

FIG. 12 shows a schematic view of an input mantissa pre-align block of the word line and input driver of FIG. 9.

FIG. 13 shows a timing diagram associated with a plurality of exponent input signals, a plurality of exponent delay output signals and a maximum exponent adding signal of FIG. 9.

FIG. 14 shows a schematic view of a relationship between a plurality of weighted input mantissas and a plurality of sums of original input exponents and original weight exponents.

### DETAILED DESCRIPTION

Embodiments of the present disclosure will be described with reference to the drawings. For clarity, some practical details will be described below. However, it should be noted that the present disclosure should not be limited by the practical details, that is, in some embodiments, the practical details are unnecessary. In addition, for simplifying the drawings, some conventional structures and elements will be simply illustrated, and repeated elements may be represented by the same reference numerals.

It will be understood that when an element (or device) is referred to as be “connected to” another element, it can be directly connected to the other element, or it can be indirectly connected to the other element, that is, intervening elements may be present. In contrast, when an element is referred to as be “directly connected to” another element, there are no intervening elements present. In addition, the terms first, second, third, etc. are used herein to describe various elements or components, and these elements or components should not be limited by these terms. Consequently, a first element or component discussed below could be termed a second element or component.

Before describing any embodiments in detail, some terms used in the following are described. A voltage level of “1” represents that the voltage is equal to a power supply voltage VDD. The voltage level of “0” represents that the voltage is equal to a ground voltage VSS. A PMOS transistor and an NMOS transistor represent a P-type MOS transistor and an N-type MOS transistor, respectively. Each transistor has a source, a drain and a gate.

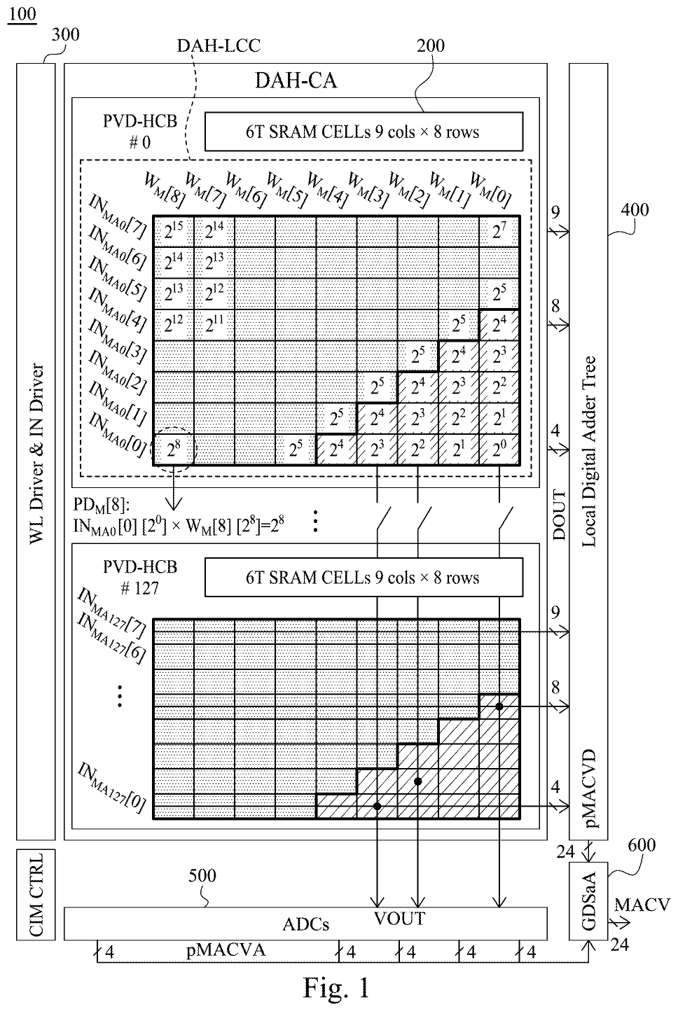

Reference is made to FIG. 1. FIG. 1 shows a schematic view of a hybrid structure 100 for computing-in-memory (CIM) applications according to a first embodiment of the present disclosure. The hybrid structure 100 for computing-in-memory applications is controlled by a first word line (WL) and a second word line (HWL). The hybrid structure 100 for computing-in-memory applications includes at least one memory cell (e.g., at least one of 6T SRAM cells (9 cols×8 rows)) and at least one digital-analog-hybrid local computing cell DAH-LCC. The at least one memory cell stores a weight (e.g., one of W_{M}[8:0]). The at least one memory cell is controlled by the first word line and includes a local bit line (LBL) transmitting the weight. The at least one digital-analog-hybrid local computing cell DAH-LCC is controlled by the second word line and has a plurality of input lines, a digital output line and an analog output line. The input lines are configured to transmit a plurality of multi-bit input values IN_{MA0}[7:0], and the at least one digital-analog-hybrid local computing cell DAH-LCC includes at least one digital local computing cell and at least one voltage local computing cell. The at least one digital local computing cell is connected to the at least one memory cell. The at least one digital local computing cell receives the weight via the local bit line and is configured to generate a digital output value DOUT on the digital output line according to a higher bit (e.g., IN_{MA0}[7]) of the multi-bit input values IN_{MA0}[7:0] multiplied by the weight. The at least one voltage local computing cell is connected to the at least one memory cell and the at least one digital local computing cell. The at least one voltage local computing cell receives the weight via the local bit line and is configured to generate an analog output value VOUT on the analog output line according to a lower bit (e.g., IN_{MA0}[0]) of the multi-bit input values IN_{MA0}[7:0] multiplied by the weight.

Therefore, the hybrid structure 100 for computing-in-memory applications of the present disclosure can perform MAC operation of higher bits in digital domain for higher accuracy while performing MAC operation of lower bits in analog domain for better parallelism.

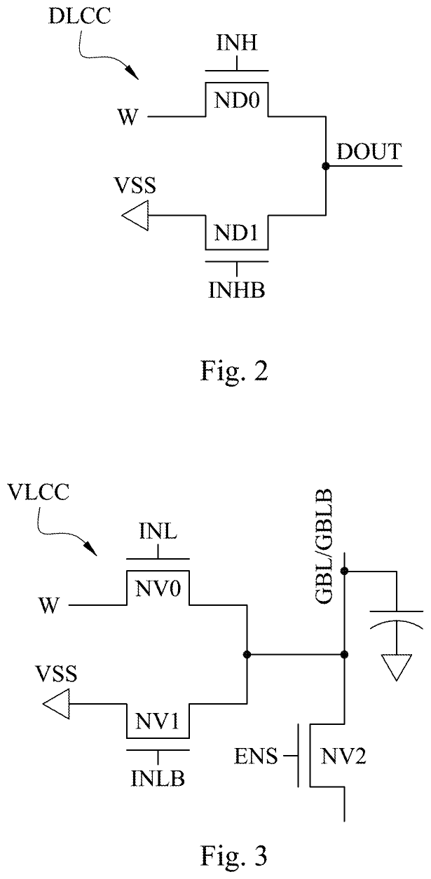

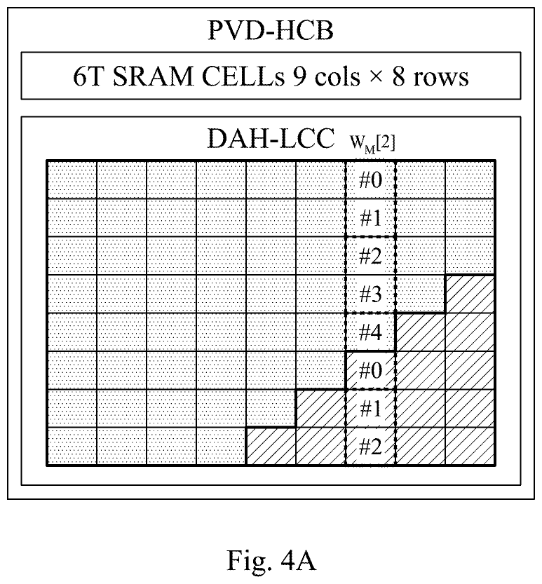

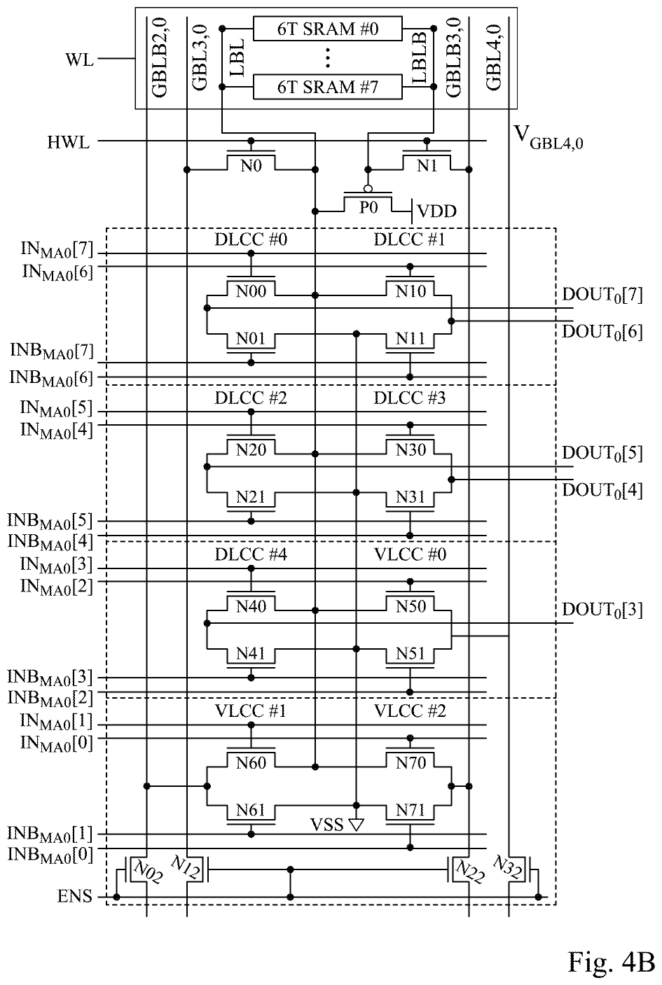

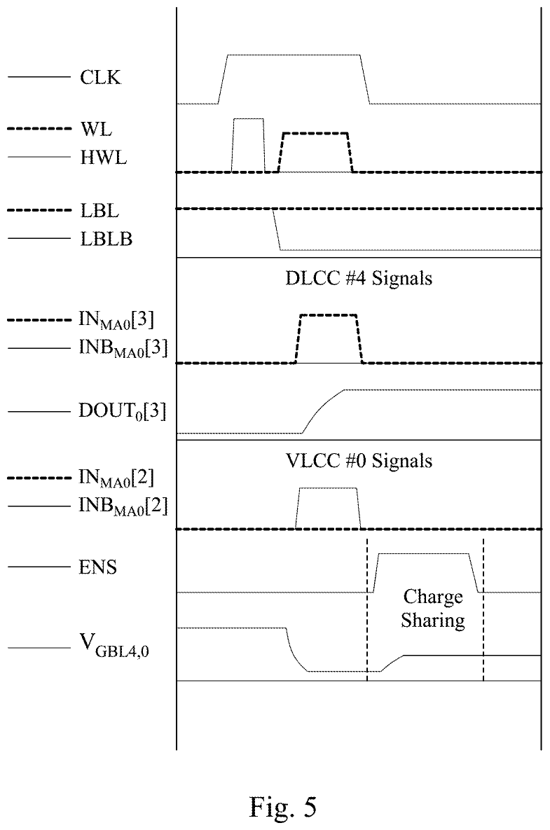

Reference is made to FIGS. 1, 2, 3, 4A, 4B and 5. FIG. 2 shows a schematic view of a digital local computing cell DLCC of a digital-analog-hybrid local computing cell DAH-LCC of FIG. 1. FIG. 3 shows a schematic view of a voltage local computing cell VLCC of the digital-analog-hybrid local computing cell DAH-LCC of FIG. 1. FIG. 4A shows a schematic view of one of a plurality of place-value dependent hybrid-domain computing blocks PVD-HCB of the hybrid structure 100 for computing-in-memory applications of FIG. 1. FIG. 4B shows a circuit diagram of one column structure of the one of the place-value dependent hybrid-domain computing blocks PVD-HCB of FIG. 4A. FIG. 5 shows a timing diagram associated with the digital local computing cell (DLCC #4) and the voltage local computing cell (VLCC #0) of FIG. 4B. In FIG. 1, the hybrid structure 100 for computing-in-memory applications includes a digital-analog-hybrid computing array DAH-CA, a word line and input driver 300, a local digital adder tree 400, an analog-to-digital converter module 500 and a global digital shift and adder circuit 600.

The digital-analog-hybrid computing array DAH-CA includes the place-value dependent hybrid-domain computing blocks PVD-HCB (e.g., PVD-HCB #0-PVD-HCB #127). The place-value dependent hybrid-domain computing blocks PVD-HCB are connected to each other. Each of the place-value dependent hybrid-domain computing blocks PVD-HCB includes a memory array 200 and a digital-analog-hybrid local computing cell DAH-LCC.

The memory array 200 includes a plurality of memory cells and is represented by “6T SRAM cells 9 cols×8 rows”. The memory array 200 is located on a top side of the digital-analog-hybrid local computing cell DAH-LCC. Each of the memory cells stores a weight (e.g., one of W_{M}[8:0]). Each of the memory cells is controlled by the first word line (WL) and includes a local bit line LBL transmitting the weight. The memory cells may be formed in a 9×8 array, but the present disclosure is not limited thereto. In one embodiment, each of the memory cells includes a six-transistor static random access memory (6T SRAM) cell, but the present disclosure is not limited thereto.

The digital-analog-hybrid local computing cell DAH-LCC includes a plurality of digital local computing cells DLCC and a plurality of voltage local computing cells VLCC. The digital local computing cells DLCC are connected to the memory cells. Each of the digital local computing cells DLCC receives the weight via the local bit line LBL and is configured to generate a digital output value DOUT (e.g., DOUT₀[7] in FIG. 4B) on the digital output line according to a higher bit INH (e.g., IN_{MA0}[7] in FIG. 4B) of the multi-bit input values (e.g., IN_{MA0}[7:0] in FIG. 4B) multiplied by the weight (e.g., W_{M}[2] in FIG. 4A). In detail, each of the digital local computing cells DLCC and the voltage local computing cells VLCC is corresponding to a place value (e.g., “PD_{M}[8]: IN_{MA0}[0]×W_{M}[8][2⁸]=2⁸” in FIG. 1). Each of the digital local computing cells DLCC includes a first digital transistor ND0 (e.g., N00 in FIG. 4B) and a second digital transistor ND1 (e.g., N01 in FIG. 4B), as shown in FIG. 2. The first digital transistor ND0 is connected between one of the memory cells (W) and the digital output line (DOUT). The first digital transistor ND0 is controlled by the higher bit INH. The second digital transistor ND1 is connected to the first digital transistor ND0. The second digital transistor ND1 is controlled by an inverted higher bit INHB (e.g., INB_{MA0}[7] in FIG. 4B) opposite to the higher bit INH. The second digital transistor ND1 is connected between the first digital transistor ND0 and the ground voltage VSS.

The voltage local computing cells VLCC are connected to the memory cells and the digital local computing cells DLCC. Each of the voltage local computing cells VLCC receives the weight via the local bit line LBL and is configured to generate an analog output value (e.g., V_{GBL4,0} in FIG. 4B) on the analog output line GBL/GBLB (e.g., GBL4,0 in FIG. 4B) according to a lower bit INL (e.g., IN_{MA0}[2] in FIG. 4B) of the multi-bit input values multiplied by the weight. In detail, each of the voltage local computing cells VLCC includes a first analog transistor NV0 (e.g., N50 in FIG. 4B), a second analog transistor NV1 (e.g., N51 in FIG. 4B) and a third analog transistor NV2 (e.g., N32 in FIG. 4B). The first analog transistor NV0 is connected between one of the memory cells (W) and the analog output line GBL/GBLB. The first analog transistor NV0 is controlled by the lower bit INL. The second analog transistor NV1 connected to the first analog transistor NV0. The second analog transistor NV1 is controlled by an inverted lower bit INLB (e.g., INB_{MA0}[2] in FIG. 4B) opposite to the lower bit INL. The second analog transistor NV1 is connected between the first analog transistor NV0 and the ground voltage VSS. The third analog transistor NV2 is connected to the first analog transistor NV0 and the second analog transistor NV1. The third analog transistor NV2 is controlled by an enable signal ENS.

For example, in FIGS. 4A and 4B, one memory cell corresponding to the weight W_{M}[2] is connected to one column structure of the digital-analog-hybrid local computing cell DAH-LCC. The one memory cell is one of 6T SRAM cells (9 cols×8 rows), i.e., one of 6T SRAM #0-6T SRAM #7. The one column structure includes a first column transistor NO, a second column transistor N1, a third column transistor P0, a global bit line (GBL3,0), a global bit line bar (GBLB3,0), five digital local computing cells (DLCC #0-DLCC #4) and three voltage local computing cells (VLCC #0-VLCC #2). The first column transistor NO is connected between the local bit line LBL and the global bit line (GBL3,0). The second column transistor N1 is connected between a local bit line bar LBLB of the one memory cell and the global bit line bar (GBLB3,0). The first column transistor NO and the second column transistor N1 are both controlled by the second word line HWL. The third column transistor P0 is connected between the local bit line LBL and the power supply voltage VDD. The third column transistor P0 is controlled by the local bit line bar LBLB.

The first one (DLCC #0) of the five digital local computing cells (DLCC #0-DLCC #4) includes a first digital transistor N00 and a second digital transistor N01. The first digital transistor N00 is connected between the one memory cell and a first digital output line. The first digital transistor N00 is controlled by a first higher bit IN_{MA0}[7]. The second digital transistor N01 is connected to the first digital transistor N00. The second digital transistor N01 is controlled by a first inverted higher bit INB_{MA0}[7] opposite to the first higher bit IN_{MA0}[7]. A first digital output value DOUT₀[7] is generated on the first digital output line according to the first higher bit IN_{MA0}[7] of the multi-bit input values IN_{MA0}[7:0] multiplied by the weight W_{M}[2].

The second one (DLCC #1) of the five digital local computing cells (DLCC #0-DLCC #4) includes a first digital transistor N10 and a second digital transistor N11. The first digital transistor N10 is connected between the one memory cell and a second digital output line. The first digital transistor N10 is controlled by a second higher bit IN_{MA0}[6]. The second digital transistor N11 is connected to the first digital transistor N10. The second digital transistor N11 is controlled by a second inverted higher bit INB_{MA0}[6] opposite to the second higher bit IN_{MA0}[6]. A second digital output value DOUT₀[6] is generated on the second digital output line according to the second higher bit IN_{MA0}[6] of the multi-bit input values IN_{MA0}[7:0] multiplied by the weight W_{M}[2].

The third one (DLCC #2) of the five digital local computing cells (DLCC #0-DLCC #4) includes a first digital transistor N20 and a second digital transistor N21. The first digital transistor N20 is connected between the one memory cell and a third digital output line. The first digital transistor N20 is controlled by a third higher bit IN_{MA0}[5]. The second digital transistor N21 is connected to the first digital transistor N20. The second digital transistor N21 is controlled by a third inverted higher bit INB_{MA0}[5] opposite to the third higher bit IN_{MA0}[5]. A third digital output value DOUT₀[5] is generated on the third digital output line according to the third higher bit IN_{MA0}[5] of the multi-bit input values IN_{MA0}[7:0] multiplied by the weight W_{M}[2].

The fourth one (DLCC #3) of the five digital local computing cells (DLCC #0-DLCC #4) includes a first digital transistor N30 and a second digital transistor N31. The first digital transistor N30 is connected between the one memory cell and a fourth digital output line. The first digital transistor N30 is controlled by a fourth higher bit IN_{MA0}[4]. The second digital transistor N31 is connected to the first digital transistor N30. The second digital transistor N31 is controlled by a fourth inverted higher bit INB_{MA0}[4] opposite to the fourth higher bit IN_{MA0}[4]. A fourth digital output value DOUT₀[4] is generated on the fourth digital output line according to the fourth higher bit IN_{MA0}[4] of the multi-bit input values IN_{MA0}[7:0] multiplied by the weight W_{M}[2].

The fifth one (DLCC #4) of the five digital local computing cells (DLCC #0-DLCC #4) includes a first digital transistor N40 and a second digital transistor N41. The first digital transistor N40 is connected between the one memory cell and a fifth digital output line. The first digital transistor N40 is controlled by a fifth higher bit IN_{MA0}[3]. The second digital transistor N41 is connected to the first digital transistor N40. The second digital transistor N41 is controlled by a fifth inverted higher bit INB_{MA0}[3] opposite to the fifth higher bit IN_{MA0}[3]. A fifth digital output value DOUT₀[3] is generated on the fifth digital output line according to the fifth higher bit IN_{MA0}[3] of the multi-bit input values IN_{MA0}[7:0] multiplied by the weight W_{M}[2]. In FIGS. 4B and 5, signals (DLCC #4 Signals) of the fifth one (DLCC #4) of the five digital local computing cells (DLCC #0-DLCC #4) includes the fifth higher bit IN_{MA0}[3], the fifth inverted higher bit INB_{MA0}[3] and the fifth digital output value DOUT₀[3]. When the voltage level of each of the clock CLK, the first word line WL and the fifth higher bit IN_{MA0}[3] is equal to “1”, the fifth digital output value DOUT₀[3] is switched to “1”, i.e., the fifth digital output value DOUT₀[3] is equal to the fifth higher bit IN_{MA0}[3] multiplied by the weight W_{M}[2].

The first one (VLCC #0) of the three voltage local computing cells (VLCC #0-VLCC #2) includes a first analog transistor N50, a second analog transistor N51 and a third analog transistor N32. The first analog transistor N50 is connected between the one memory cell and a first analog output line (GBL4,0). The first analog transistor N50 is controlled by a first lower bit IN_{MA0}[2]. The second analog transistor N51 is connected to the first analog transistor N50. The second analog transistor N51 is controlled by a first inverted lower bit INB_{MA0}[2] opposite to the first lower bit IN_{MA0}[2]. The third analog transistor N32 is connected to the first analog transistor N50 and the second analog transistor N51. The third analog transistor N32 is controlled by the enable signal ENS. A first analog output value (V_{GBL4,0}) is generated on the first analog output line (GBL4,0) according to the first lower bit IN_{MA0}[2] of the multi-bit input values IN_{MA0}[7:0] multiplied by the weight W_{M}[2]. In FIGS. 4B and 5, signals (VLCC #0 Signals) of the first one (VLCC #0) of the three voltage local computing cells (VLCC #0-VLCC #2) includes the first lower bit IN_{MA0}[2], the first inverted lower bit INB_{MA0}[2], the enable signal ENS and the first analog output value (V_{GBL4,0}). When the voltage level of the first lower bit IN_{MA0}[2] is equal to “0” and the voltage level of each of the clock CLK and the first word line WL is equal to “1”, the first analog output value (V_{GBL4,0}) is switched to “0”, i.e., the first analog output value (V_{GBL4,0}) is equal to the first lower bit IN_{MA0}[2] multiplied by the weight W_{M}[2]. Next, when the voltage level of the enable signal ENS is equal to “1”, the first analog output value (V_{GBL4,0}) is charged by charge sharing.

The second one (VLCC #1) of the three voltage local computing cells (VLCC #0-VLCC #2) includes a first analog transistor N60, a second analog transistor N61 and a third analog transistor N02. The first analog transistor N60 is connected between the one memory cell and a second analog output line (GBLB2,0). The first analog transistor N60 is controlled by a second lower bit IN_{MA0}[1]. The second analog transistor N61 is connected to the first analog transistor N60. The second analog transistor N61 is controlled by a second inverted lower bit INB_{MA0}[1] opposite to the second lower bit IN_{MA0}[1]. The third analog transistor N02 is connected to the first analog transistor N60 and the second analog transistor N61. The third analog transistor N02 is controlled by the enable signal ENS. A second analog output value (V_{GBLB2,0}) is generated on the second analog output line (GBLB2,0) according to the second lower bit IN_{MA0}[1] of the multi-bit input values IN_{MA0}[7:0] multiplied by the weight W_{M}[2].

The third one (VLCC #2) of the three voltage local computing cells (VLCC #0-VLCC #2) includes a first analog transistor N70, a second analog transistor N71 and a third analog transistor N22. The first analog transistor N70 is connected between the one memory cell and a third analog output line (GBLB3,0). The first analog transistor N70 is controlled by a third lower bit IN_{MA0}[0]. The second analog transistor N71 is connected to the first analog transistor N70. The second analog transistor N71 is controlled by a third inverted lower bit INB_{MA0}[0] opposite to the third lower bit IN_{MA0}[0]. The third analog transistor N22 is connected to the first analog transistor N70 and the second analog transistor N71. The third analog transistor N22 is controlled by the enable signal ENS. A third analog output value (V_{GBLB3,0}) is generated on the third analog output line (GBLB3,0) according to the third lower bit IN_{MA0}[0] of the multi-bit input values IN_{MA0}[7:0] multiplied by the weight W_{M}[2].

The one column structure further includes a third analog transistor N12 controlled by the enable signal ENS. The third analog transistor N12 is connected to the first column transistor NO and the third analog transistor N22. Each of the first digital transistors N00, N10, N20, N30, N40 of FIG. 4B is corresponding to the first digital transistor ND0 of FIG. 2. Each of the second digital transistors N01, N11, N21, N31, N41 of FIG. 4B is corresponding to the second digital transistor ND1 of FIG. 2. Each of the first analog transistors N50, N60, N70 of FIG. 4B is corresponding to the first analog transistor NV0 of FIG. 3. Each of the second analog transistors N51, N61, N71 of FIG. 4B is corresponding to the second analog transistor NV1 of FIG. 3. Each of the third analog transistors N02, N12, N22, N32 of FIG. 4B is corresponding to the third analog transistor NV2 of FIG. 3. Each of the first column transistor NO, the second column transistor N1, the first digital transistors N00, N10, N20, N30, N40, the second digital transistors N01, N11, N21, N31, N41, the first analog transistors N50, N60, N70, the second analog transistors N51, N61, N71 and the third analog transistors N02, N12, N22, N32 is the NMOS transistor. The third column transistor P0 is the PMOS transistor.

The word line and input driver 300 is connected to the digital-analog-hybrid computing array DAH-CA via the first word line WL, the second word line HWL and the input lines. The word line and input driver 300 is represented by “WL Driver & IN Driver” and is located on a left side of the digital-analog-hybrid computing array DAH-CA. The word line and input driver 300 generates the voltage levels of the first word line WL, the second word line HWL and the multi-bit input values IN_{MA0}[7:0]-IN_{MA127}[7:0] to drive the place-value dependent hybrid-domain computing blocks PVD-HCB.

The local digital adder tree 400 is connected to the at least one digital local computing cell DLCC via the digital output line. The local digital adder tree 400 is represented by “Local Digital Adder Tree” and is located on a right side of the digital-analog-hybrid computing array DAH-CA. In FIGS. 4A and 4B, the number of the at least one digital local computing cell (DLCC #0-DLCC #4) is plural. The digital local computing cells (DLCC #0-DLCC #4) are configured to generate the digital output values DOUT₀[7:3] on the digital output lines according to the higher bits (IN_{MA0}[7:3]) of the multi-bit input values IN_{MA0}[7:0] multiplied by the weight W_{M}[2]. The local digital adder tree 400 is configured to receive the digital output values DOUT₀[7:3] and add the digital output values DOUT0[7:3] to generate a digital partial multiply-and-accumulate value pMACVD.

The analog-to-digital converter module 500 includes at least one analog-to-digital converter (ADCs). The at least one analog-to-digital converter is connected to the voltage local computing cells VLCC via the analog output line GBL/GBLB. The number of the at least one digital-analog-hybrid local computing cell DAH-LCC is plural. The digital-analog-hybrid local computing cells DAH-LCC are configured to generate the analog output values (e.g., V_{GBL4,0}, V_{GBL4,1}, . . . , V_{GBL4,127}) on the analog output line (e.g., GBL4,0). An analog shared output value (V_{GBL4}) is formed by charge sharing according to the analog output values (V_{GBL4,0}, V_{GBL4,1}, . . . , V_{GBL4,127}), and the at least one analog-to-digital converter (ADCs) is configured to receive the analog shared output value (V_{GBL4}) and convert the analog shared output value (V_{GBL4}) into an analog partial multiply-and-accumulate value pMACVA.

The global digital shift and adder circuit 600 (GDSaA) is connected to the local digital adder tree 400 and the at least one analog-to-digital converter (ADCs) of the analog-to-digital converter module 500. The local digital adder tree 400 is connected between the at least one digital local computing cell DLCC of the digital-analog-hybrid local computing cell DAH-LCC and the global digital shift and adder circuit 600. The at least one analog-to-digital converter (ADCs) of the analog-to-digital converter module 500 is connected between the at least one voltage local computing cell VLCC of the digital-analog-hybrid local computing cell DAH-LCC and the global digital shift and adder circuit 600. The global digital shift and adder circuit 600 is configured to calculate the digital partial multiply-and-accumulate value pMACVD and the analog partial multiply-and-accumulate value pMACVA to generate a multiply-and-accumulate value MACV.

In one embodiment, the local digital adder tree 400 is configured to generate a 24-bit digital partial multiply-and-accumulate value pMACVD. The analog-to-digital converter module 500 includes eight analog-to-digital converters (ADCs) which are configured to generate eight 4-bit analog partial multiply-and-accumulate values pMACVA. The global digital shift and adder circuit 600 is configured to calculate the 24-bit digital partial multiply-and-accumulate value pMACVD and the eight 4-bit analog partial multiply-and-accumulate values pMACVA to generate a 24-bit multiply-and-accumulate value MACV, but the present disclosure is not limited thereto.

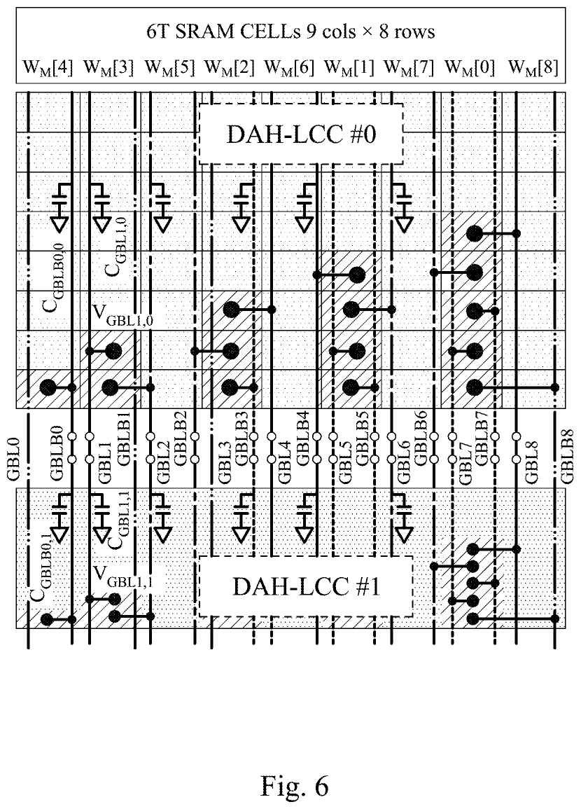

Reference is made to FIGS. 1, 2, 3, 4A, 4B and 6. FIG. 6 shows a schematic view of weight scramble of the one of the place-value dependent hybrid-domain computing blocks PVD-HCB of FIG. 1. The memory cells of the memory array 200 include a first memory cell storing a first weight W_{M}[4], a second memory cell storing a second weight W_{M}[3], a third memory cell storing a third weight W_{M}[5], a fourth memory cell storing a fourth weight W_{M}[2], a fifth memory cell storing a fifth weight W_{M}[6], a sixth memory cell storing a sixth weight W_{M}[1], a seventh memory cell storing a seventh weight W_{M}[7], an eighth memory cell storing an eighth weight W_{M}[0] and a ninth memory cell storing a ninth weight W_{M}[8]. In the digital-analog-hybrid local computing cell (DAH-LCC #0) of FIG. 6, the number of the at least one digital local computing cell DLCC is equal to 57, and the number of the at least one voltage local computing cell (VLCC) is equal to 15. The digital-analog-hybrid local computing cell (DAH-LCC #0) includes a first column structure, a second column structure, a third column structure, a fourth column structure, a fifth column structure, a sixth column structure, a seventh column structure, an eighth column structure and a ninth column structure. The digital-analog-hybrid local computing cells (DAH-LCC #0, DAH-LCC #1) are corresponding to the place-value dependent hybrid-domain computing blocks (PVD-HCB #0, PVD-HCB #1).

The first column structure is connected to the first memory cell storing the first weight W_{M}[4]. The first column structure includes a first global bit line GBL0, a first global bit line bar GBLB0, seven of the digital local computing cells DLCC and one of the voltage local computing cells VLCC. The second column structure is connected to the second memory cell storing a second weight W_{M}[3]. The second column structure includes a second global bit line GBL1, a second global bit line bar GBLB1, six of the digital local computing cells DLCC and two of the voltage local computing cells VLCC. The third column structure is connected to the third memory cell storing the third weight W_{M}[5]. The third column structure includes a third global bit line GBL2, a third global bit line bar GBLB2 and first eight of the digital local computing cells DLCC. The one of the voltage local computing cells VLCC of the first column structure is connected to the first global bit line bar GBLB0. The two of the voltage local computing cells VLCC of the second column structure are connected to the second global bit line GBL1 and the third global bit line GBL2, respectively, and the second column structure is connected between the first column structure and the third column structure.

The fourth column structure is connected to the fourth memory cell storing a fourth weight W_{M}[2]. The fourth column structure includes a fourth global bit line GBL3, a fourth global bit line bar GBLB3, five of the digital local computing cells DLCC and three of the voltage local computing cells VLCC. The fifth column structure is connected to the fifth memory cell storing the fifth weight W_{M}[6]. The fifth column structure includes a fifth global bit line GBL4, a fifth global bit line bar GBLB4 and second eight of the digital local computing cells DLCC. The three of the voltage local computing cells VLCC of the fourth column structure are connected to the fifth global bit line GBL4, the third global bit line bar GBLB2 and the fourth global bit line bar GBLB3, respectively, and the fourth column structure is connected between the third column structure and the fifth column structure.

The sixth column structure is connected to the sixth memory cell storing a sixth weight W_{M}[1]. The sixth column structure includes a sixth global bit line GBL5, a sixth global bit line bar GBLB5, four of the digital local computing cells DLCC and four of the voltage local computing cells VLCC. The seventh column structure is connected to the seventh memory cell storing a seventh weight W_{M}[7]. The seventh column structure includes a seventh global bit line GBL6, a seventh global bit line bar GBLB6 and third eight of the digital local computing cells DLCC. The four of the voltage local computing cells VLCC of the sixth column structure are connected to the fifth global bit line bar GBLB4, the seventh global bit line GBL6, the sixth global bit line GBL5 and the sixth global bit line bar GBLB5, respectively, and the sixth column structure is connected between the fifth column structure and the seventh column structure.

The eighth column structure is connected to the eighth memory cell storing an eighth weight W_{M}[0]. The eighth column structure includes an eighth global bit line GBL7, an eighth global bit line bar GBLB7, three of the digital local computing cells DLCC and five of the voltage local computing cells VLCC. The ninth column structure is connected to the ninth memory cell storing a ninth weight W_{M}[8]. The ninth column structure includes a ninth global bit line GBL8, a ninth global bit line bar GBLB8 and fourth eight of the digital local computing cells DLCC. The five of the voltage local computing cells VLCC of the eighth column structure are connected to the ninth global bit line GBL8, the seventh global bit line bar GBLB6, the eighth global bit line bar GBLB7, the eighth global bit line GBL7 and the ninth global bit line bar GBLB8, respectively, and the eighth column structure is connected between the seventh column structure and the ninth column structure.

In the digital-analog-hybrid local computing cell DAH-LCC of each of the place-value dependent hybrid-domain computing blocks PVD-HCB, each of the first global bit line GBL0, the first global bit line bar GBLB0, the second global bit line GBL1, the second global bit line bar GBLB1, the third global bit line GBL2, the third global bit line bar GBLB2, the fourth global bit line GBL3, the fourth global bit line bar GBLB3, the fifth global bit line GBL4, the fifth global bit line bar GBLB4, the sixth global bit line GBL5, the sixth global bit line bar GBLB5, the seventh global bit line GBL6, the seventh global bit line bar GBLB6, the eighth global bit line GBL7, the eighth global bit line bar GBLB7, the ninth global bit line GBL8 and the ninth global bit line bar GBLB8 has a parasitic capacitor (e.g., C_{GBLB0,0}, C_{GBLB0,1}, C_{GBL1,0}, C_{GBL1,1}) and an analog output value (e.g., V_{GBL1,0}, V_{GBL1,1}) for charge sharing.

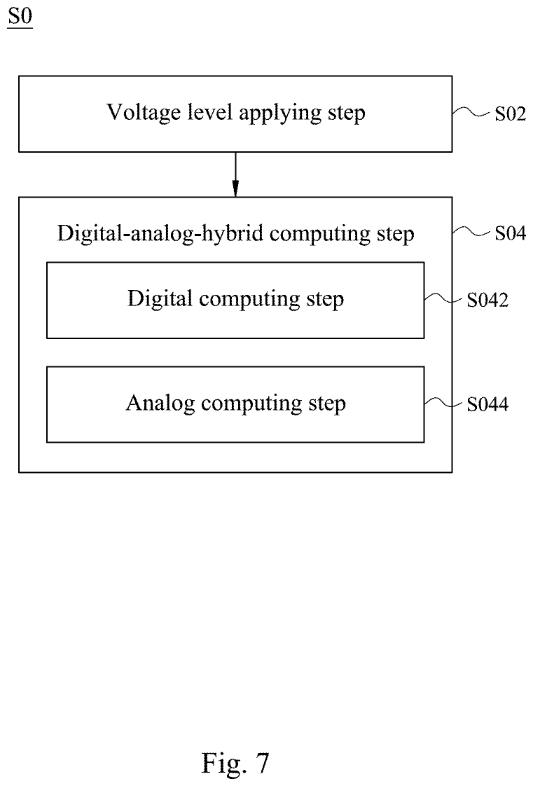

Reference is made to FIGS. 1, 2, 3, 4A, 4B, 5 and 7. FIG. 7 shows a flow chart of a computing method S0 of a hybrid structure 100 for computing-in-memory applications according to a second embodiment of the present disclosure. The computing method S0 includes performing a voltage level applying step S02 and a digital-analog-hybrid computing step S04. The voltage level applying step S02 includes applying a plurality of voltage levels to a first word line WL, a second word line HWL, a plurality of input lines of at least one digital-analog-hybrid local computing cell DAH-LCC and a weight of at least one memory cell. The digital-analog-hybrid computing step S04 includes performing a digital computing step S042 and an analog computing step S044. The digital computing step S042 includes configuring at least one digital local computing cell DLCC of the at least one digital-analog-hybrid local computing cell DAH-LCC to generate a digital output value DOUT on a digital output line according to a higher bit (e.g., IN_{MA0}[7]) of a plurality of multi-bit input values IN_{MA0}[7:0] multiplied by the weight. The analog computing step S044 includes configuring at least one voltage local computing cell VLCC of the at least one digital-analog-hybrid local computing cell DAH-LCC to generate an analog output value VOUT on an analog output line according to a lower bit (e.g., IN_{MA0}[0]) of the multi-bit input values IN_{MA0}[7:0] multiplied by the weight. Therefore, the computing method S0 of the present disclosure can perform MAC operation of higher bits in digital domain for higher accuracy while performing MAC operation of lower bits in analog domain for better parallelism.

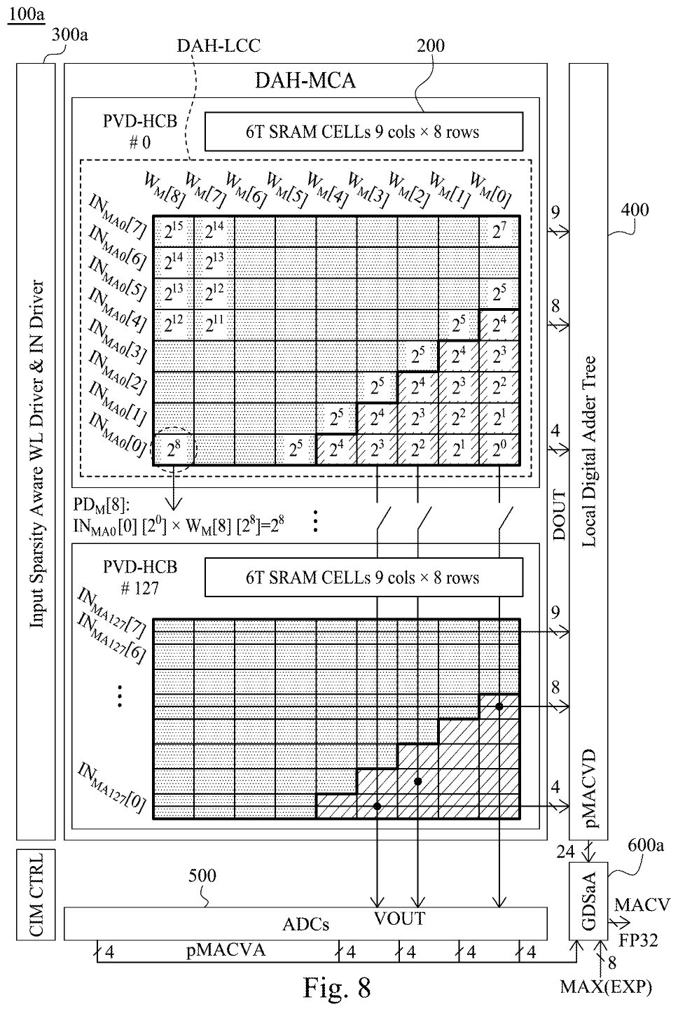

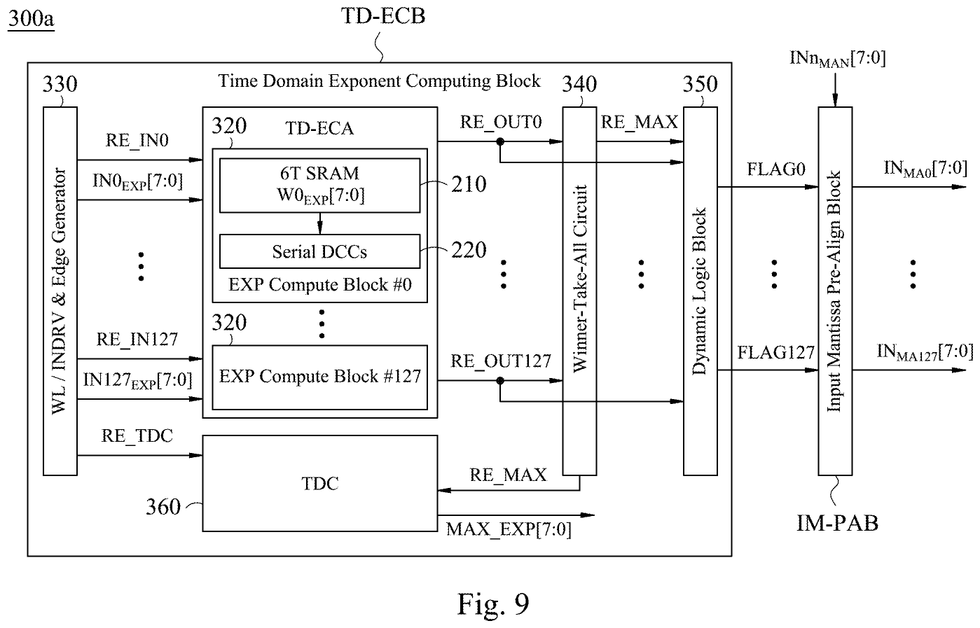

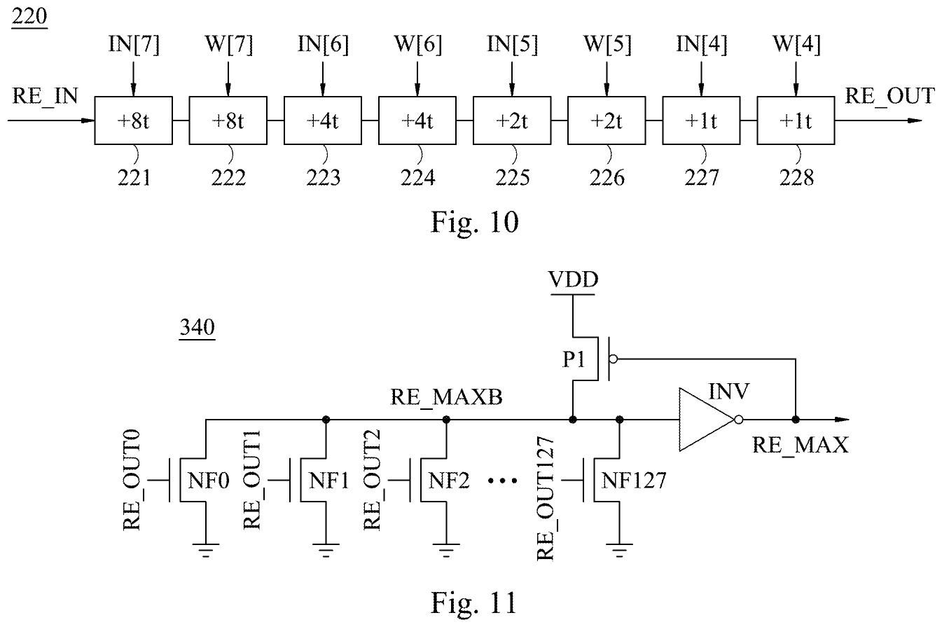

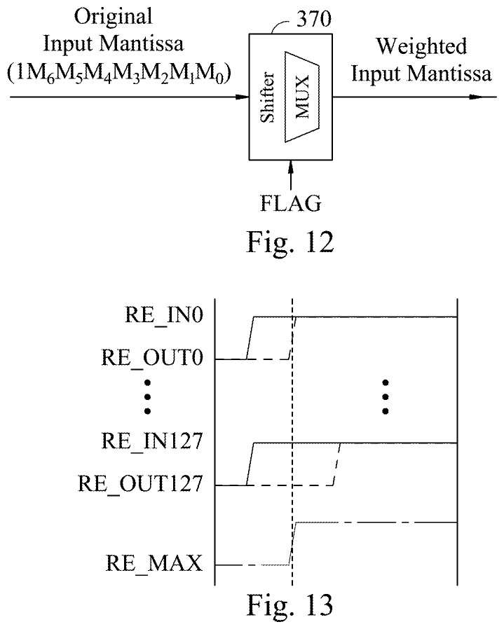

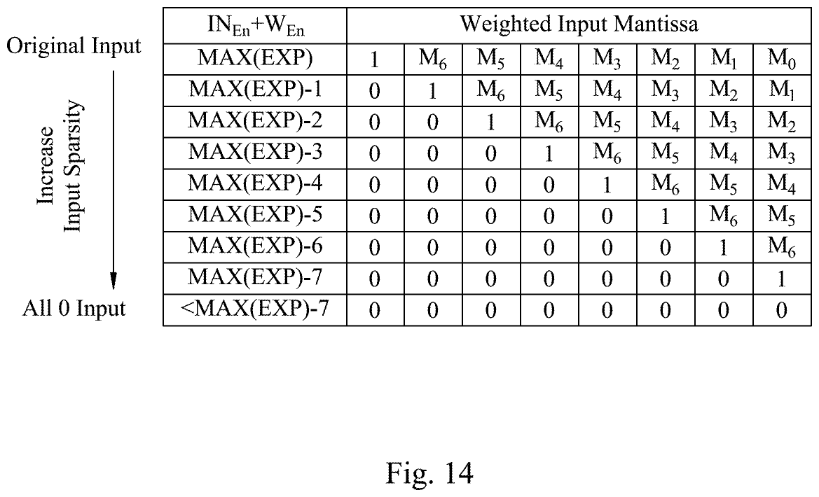

Reference is made to FIGS. 1, 2, 3, 4A, 4B, 8, 9, 10, 11, 12, 13 and 14. FIG. 8 shows a schematic view of a hybrid structure 100a for computing-in-memory applications according to a third embodiment of the present disclosure. FIG. 9 shows a schematic view of a word line and input driver 300a of the hybrid structure 100a for computing-in-memory applications of FIG. 8. FIG. 10 shows a schematic view of a serial delay computing circuit 220 (Serial DCCs) of the word line and input driver 300a of FIG. 9. FIG. 11 shows a schematic view of a winner-take-all circuit 340 of the word line and input driver 300a of FIG. 9. FIG. 12 shows a schematic view of an input mantissa pre-align block IM-PAB of the word line and input driver 300a of FIG. 9. FIG. 13 shows a timing diagram associated with a plurality of exponent input signals RE_IN0-RE_IN127, a plurality of exponent delay output signals RE_OUT0-RE_OUT127 and a maximum exponent adding signal RE_MAX of FIG. 9. FIG. 14 shows a schematic view of a relationship between a plurality of weighted input mantissas (IN_{MA0}[7:0]-IN_{MA127}[7:0]) and a plurality of sums of original input exponents IN0_{EXP}[7:0]-IN127_{EXP}[7:0] and original weight exponents W0_{EXP}[7:0]-W127_{EXP}[7:0].

The hybrid structure 100a for computing-in-memory applications is configured to perform floating point operation and includes a digital-analog-hybrid mantissa computing array DAH-MCA, a word line and input driver 300a, a local digital adder tree 400, an analog-to-digital converter module 500 and a global digital shift and adder circuit 600a. The structure of the digital-analog-hybrid mantissa computing array DAH-MCA, the local digital adder tree 400 and the analog-to-digital converter module 500 of FIG. 8 is the same as the structure of the digital-analog-hybrid computing array DAH-CA, the local digital adder tree 400 and the analog-to-digital converter module 500 of FIG. 1, and will not be described again herein.

The word line and input driver 300a is connected to the digital-analog-hybrid mantissa computing array DAH-MCA via the first word line WL, the second word line HWL and the input lines. The word line and input driver 300a is represented by “Input Sparsity Aware WL Driver & IN Driver” and is located on a left side of the digital-analog-hybrid mantissa computing array DAH-MCA. The word line and input driver 300a generates the voltage levels of the first word line WL, the second word line HWL and the multi-bit input values IN_{MA0}[7:0]-IN_{MA127}[7:0] to drive the place-value dependent hybrid-domain computing blocks PVD-HCB. In detail, the word line and input driver 300a includes a time domain exponent computing block TD-ECB and the input mantissa pre-align block IM-PAB. The time domain exponent computing block TD-ECB is configured to compute the original input exponents IN0_{EXP}[7:0]-IN127_{EXP}[7:0] and the original weight exponents W0_{EXP}[7:0]-W127_{EXP}[7:0]. The time domain exponent computing block TD-ECB includes a time domain exponent computing array TD-ECA, a word line input driver unit 330, a winner-take-all circuit 340 and a dynamic logic block 350.

The time domain exponent computing array TD-ECA is configured to delay a plurality of exponent input signals RE_IN0-RE_IN127 by a plurality of delay time periods to generate a plurality of exponent delay output signals RE_OUT0-RE_OUT127. Each of the delay time periods is determined by adding one of the original input exponents IN0_{EXP}[7:0]-IN127_{EXP}[7:0] and one of the original weight exponents W0_{EXP}[7:0]-W127_{EXP}[7:0]. In detail, the exponent input signals RE_IN0-RE_IN127 are rising edge input signals and are the same with each other. The time domain exponent computing array TD-ECA includes a plurality of exponent computing modules 320 (e.g., EXP compute Block #0-EXP compute Block #127), and each of the exponent computing modules 320 includes a memory array unit 210 and a serial delay computing circuit 220 (Serial DCCs).

The memory array unit 210 includes a plurality of memory cells. The memory cells store the one of the original weight exponents W0_{EXP}[7:0]-W127_{EXP}[7:0]. In one embodiment, the memory cells may be formed in an 8×16 array, and each of the memory cells includes a six-transistor static random access memory (6T SRAM) cell, but the present disclosure is not limited thereto.

The serial delay computing circuit 220 is connected to the memory array unit 210. The serial delay computing circuit 220 is configured to receive one of the original input exponents IN0_{EXP}[7:0]-IN127_{EXP}[7:0] and the one of the original weight exponents W0_{EXP}[7:0]-W127_{EXP}[7:0], and delay each of the exponent input signals RE_IN0-RE_IN127 by each of the delay time periods to generate each of the exponent delay output signals RE_OUT0-RE_OUT127. In detail, each of the original input exponents IN0_{EXP}[7:0]-IN127_{EXP}[7:0] may be represented by bits IN[7], IN[6], IN[5], IN[4], IN[3], IN[2], IN[1], IN[0]. Each of the original weight exponents W0_{EXP}[7:0]-W127_{EXP}[7:0] may be represented by bits W[7], W[6], W[5], W[4], W[3], W[2], W[1], W[0]. In FIG. 10, the serial delay computing circuit 220 includes a plurality of time delay circuits serially connected to each other, and the time delay circuits include two first time delay circuits 221, 222, two second time delay circuits 223, 224, two third time delay circuits 225, 226 and two fourth time delay circuits 227, 228.

The two first time delay circuits 221, 222 receive the bits IN[7], W[7], respectively. One (221) of the two first time delay circuits 221, 222 is configured to determine whether to delay eight unit time periods (+8t) according to a first bit (IN[7]) of the one of the original input exponents IN0_{EXP}[7:0]-IN127_{EXP}[7:0], and another (222) of the two first time delay circuits 221, 222 is connected to the one (221) of the two first time delay circuits 221, 222 and configured to determine whether to delay the eight unit time periods (+8t) according to a first bit (W[7]) of the one of the original weight exponents W0_{EXP}[7:0]-W127_{EXP}[7:0]. For example, in response to determining that the first bit (IN[7]) is equal to one, the first time delay circuit 221 determines to bypass and not to delay. In response to determining that the first bit (IN[7]) is equal to zero, the first time delay circuit 221 determines to delay the exponent input signal RE_IN (e.g., one of the exponent input signals RE_IN0-RE_IN127) by the eight unit time periods (+8t).

The two second time delay circuits 223, 224 receive the bits IN[6], W[6], respectively. One (223) of the two second time delay circuits 223, 224 is connected to the another (222) of the two first time delay circuits 221, 222 and configured to determine whether to delay four unit time periods (+4t) according to a second bit (IN[6]) of the one of the original input exponents IN0_{EXP}[7:0]-IN127_{EXP}[7:0], and another (224) of the two second time delay circuits 223, 224 is connected to the one (223) of the two second time delay circuits 223, 224 and configured to determine whether to delay the four unit time periods (+4t) according to a second bit (W[6]) of the one of the original weight exponents W0_{EXP}[7:0]-W127_{EXP}[7:0].

The third time delay circuits 225, 226 receive the bits IN[5], W[5], respectively. One (225) of the two third time delay circuits 225, 226 is connected to the another (224) of the two second time delay circuits 223, 224 and configured to determine whether to delay two unit time periods (+2t) according to a third bit (IN[5]) of the one of the original input exponents IN0_{EXP}[7:0]-IN127_{EXP}[7:0], and another (226) of the two third time delay circuits 225, 226 is connected to the one (225) of the two third time delay circuits 225, 226 and configured to determine whether to delay the two unit time periods (+2t) according to a third bit (W[5]) of the one of the original weight exponents W0_{EXP}[7:0]-W127_{EXP}[7:0].

The fourth time delay circuits 227, 228 receive the bits IN[4], W[4], respectively. One (227) of the two fourth time delay circuits 227, 228 is connected to the another (226) of the two third time delay circuits 225, 226 and configured to determine whether to delay one unit time period (+1t) according to a fourth bit (IN[4]) of the one of the original input exponents IN0_{EXP}[7:0]-IN127_{EXP}[7:0], and another (228) of the two fourth time delay circuits 227, 228 is connected to the one (227) of the two fourth time delay circuits 227, 228 and configured to determine whether to delay the one unit time period (+1t) according to a fourth bit (W[4]) of the one of the original weight exponents W0_{EXP}[7:0]-W127_{EXP}[7:0].

Each of the delay time periods is equal to a sum of total unit time periods delayed by all of the time delay circuits of the serial delay computing circuit 220. Each of the delay time periods has a negative correlation with a sum of the one of the original input exponents IN0_{EXP}[7:0]-IN127_{EXP}[7:0] and the one of the original weight exponents W0_{EXP}[7:0]-W127_{EXP}[7:0]. In FIG. 10, each of the delay time periods represents a delay time difference between the exponent delay output signal RE_OUT (e.g., one of the exponent delay output signals RE_OUT0-RE_OUT127) and the exponent input signal RE_IN (e.g., one of the exponent input signals RE_IN0-RE_IN127). The serial delay computing circuit 220 is configured to process most significant 4 bits (IN[7]-IN[4]) of the one of the original input exponents IN0_{EXP}[7:0]-IN127_{EXP}[7:0] and most significant 4 bits (W[7]-W[4]) of the one of the original weight exponents W0_{EXP}[7:0]-W127_{EXP}[7:0], i.e., the serial delay computing circuit 220 is configured to process one round, and the one round including adding the most significant 4 bits (IN[7]-IN[4]) and the most significant 4 bits (W[7]-W[4]). In another embodiment, the serial delay computing circuit 220 can be configured to process two rounds including a first round and a second round. The first round includes adding the most significant 4 bits (IN[7]-IN[4]) and the most significant 4 bits (W[7]-W[4]), i.e., IN_{EXPM4b}+W_{EXPM4b}. In the first round, the two first time delay circuits 221, 222, the two second time delay circuits 223, 224, the two third time delay circuits 225, 226 and the two fourth time delay circuits 227, 228 receive the bits IN[7], W[7], IN[6], W[6], IN[5], W[5], IN[4], W[4], respectively. The second round includes adding least significant 4 bits (IN[3]-IN[0]) of the one of the original input exponents IN0_{EXP}[7:0]-IN127_{EXP}[7:0] and least significant 4 bits (W[3]-W[0]) of the one of the original weight exponents W0_{EXP}[7:0]-W127_{EXP}[7:0], i.e., IN_{EXPL4b}+W_{EXPL4b}. In the second round, the two first time delay circuits 221, 222, the two second time delay circuits 223, 224, the two third time delay circuits 225, 226 and the two fourth time delay circuits 227, 228 receive the bits IN[3], W[3], IN[2], W[2], IN[1], W[1], IN[0], W[0], respectively.

The word line input driver unit 330 is connected to each of the exponent computing modules 320 via word lines, first input lines and second input lines. The word line input driver unit 330 generates a plurality of exponent input signals RE_IN0-RE_IN127, RE_TDC and the original input exponents IN0_{EXP}[7:0]-IN127_{EXP}[7:0]. The first input lines are configured to transmit the exponent input signals RE_IN0-RE_IN127, RE_TDC. The exponent input signals RE_IN0-RE_IN127, RE_TDC are rising edge input signals and are the same with each other. The second input lines are configured to transmit the original input exponents IN0_{EXP}[7:0]-IN127_{EXP}[7:0]. The word line input driver unit 330 is represented by “WL/INDRV & Edge Generator” and is located on a left side of the exponent computing modules 320.

The winner-take-all circuit 340 is connected to the time domain exponent computing array TD-ECA and configured to find out one of the exponent delay output signals RE_OUT0-RE_OUT127 as a maximum exponent adding signal RE_MAX. The one of the exponent delay output signals RE_OUT0-RE_OUT127 is corresponding to a minimum one of the delay time periods. In detail, in FIG. 11, the winner-take-all circuit 340 includes a plurality of first transistors NF0-NF127 (i.e., NF0, NF1, NF2, . . . , NF127), a second transistor P1 and an inverter INV. The first transistors NF0-NF127 are controlled by the exponent delay output signals RE_OUT0-RE_OUT127, respectively. The second transistor P1 is connected to the first transistors NF0-NF127 and controlled by the maximum exponent adding signal RE_MAX. The inverter INV has an input node and an output node. The input node is connected to the first transistors NF0-NF127 and the second transistor P1. The input node receives a maximum exponent adding signal bar RE_MAXB. The output node generates the maximum exponent adding signal RE_MAX according to the one of the exponent delay output signals RE_OUT0-RE_OUT127. Each of the first transistors NF0-NF127 is the NMOS transistor. The second transistor P1 is the PMOS transistor.

The dynamic logic block 350 is connected to the winner-take-all circuit 340 and configured to compare the maximum exponent adding signal RE_MAX with the exponent delay output signals RE_OUT0-RE_OUT127 to generate a plurality of flags FLAG0-FLAG127. In detail, the dynamic logic block 350 includes a plurality of dynamic logic circuits. The dynamic logic circuits are connected to the winner-take-all circuit 340 and the time domain exponent computing array TD-ECA. Each of the dynamic logic circuits is coupled to the maximum exponent adding signal RE_MAX and each of the exponent delay output signals RE_OUT0-RE_OUT127, and configured to generate the flags FLAG0-FLAG127 by comparing the maximum exponent adding signal RE_MAX and each of the exponent delay output signals RE_OUT0-RE_OUT127. Each of the dynamic logic circuits may be implemented by comparators or time to digital converters. Each of the flags FLAG0-FLAG127 is a multi-bit signal and has a negative correlation with a sum of the one of the original input exponents IN0_{EXP}[7:0]-IN127_{EXP}[7:0] and the one of the original weight exponents W0_{EXP}[7:0]-W127_{EXP}[7:0].

In one embodiment, the time domain exponent computing block TD-ECB further includes a time to digital converter 360 (TDC). The time to digital converter 360 is connected to the winner-take-all circuit 340. The time to digital converter 360 is configured to receive the maximum exponent adding signal RE_MAX from the winner-take-all circuit 340 and generate a maximum input exponent MAX_EXP[7:0] according to the maximum exponent adding signal RE_MAX. In detail, the time to digital converter 360 is connected between the word line input driver unit 330 and the winner-take-all circuit 340. The time to digital converter 360 is configured to receive the maximum exponent adding signal RE_MAX and the exponent input signal RE_TDC, and generate the maximum input exponent MAX_EXP[7:0] according to the exponent input signal RE_TDC and the maximum exponent adding signal RE_MAX. The maximum input exponent MAX_EXP[7:0] and the weighted input mantissas (IN_{MA0}[7:0]-IN_{MA127}[7:0]) are configured to perform the MAC operation of the mantissa part.

The input mantissa pre-align block IM-PAB is connected to the time domain exponent computing block TD-ECB. The input mantissa pre-align block IM-PAB is configured to receive a plurality of original input mantissas INn_{MAN}[7:0] (e.g., IN0_{MAN}[7:0]-IN127_{MAN}[7:0], one may be “1M₆M₅M₄M₃M₂M₁M₀”) and shift the original input mantissas INn_{MAN}[7:0] according to the flags FLAG0-FLAG127 to generate a plurality of weighted input mantissas (IN_{MA0}[7:0]-IN_{MA127}[7:0]). n may be equal to 0-127. Sparsity of the weighted input mantissas (IN_{MA0}[7:0]-IN_{MA127}[7:0]) is greater than sparsity of the original input mantissas INn_{MAN}[7:0]. In detail, the input mantissa pre-align block IM-PAB includes a plurality of shifters 370. The shifters 370 are connected to the dynamic logic block 350. Each of the shifters 370 is configured to receive one (1M₆M₅M₄M₃M₂M₁M₀) of the original input mantissas INn_{MAN}[7:0] and shift the one of the original input mantissas INn_{MAN}[7:0] according to one (FLAG) of the flags FLAG0-FLAG127 to generate one of the weighted input mantissas (IN_{MA0}[7:0]-IN_{MA127}[7:0]), and each of the shifters 370 includes at least one multiplexer (MUX), as shown in FIG. 12.

In FIG. 14, the original input mantissas INn_{MAN}[7:0] is corresponding to “1M₆M₅M₄M₃M₂M₁M₀”. Each of the bits M₆, M₅, M₄, M₃, M₂, M₁, M₀ may be 1 or 0. The input mantissa pre-align block IM-PAB is configured to shift the original input mantissas INn_{MAN}[7:0] according to the flags FLAG0-FLAG127 to generate the weighted input mantissas (IN_{MA0}[7:0]-IN_{MA127}[7:0]). The flags FLAG0-FLAG127 are corresponding to the sums of the original input exponents IN0_{EXP}[7:0]-IN127_{EXP}[7:0] and the original weight exponents W0_{EXP}[7:0]-W127_{EXP}[7:0].

In detail, when the sum (IN_{En}+W_{En}) of one of the original input exponents IN0_{EXP}[7:0]-IN127_{EXP}[7:0] and one of the original weight exponents W0_{EXP}[7:0]-W127_{EXP}[7:0] is equal to a maximum exponent adding value MAX(EXP), the weighted input mantissa (IN_{MAn}[7:0]) is corresponding to “1M₆M₅M₄M₃M₂M₁M₀”. When the sum (IN_{En}+W_{En}) of one of the original input exponents IN0_{EXP}[7:0]-IN127_{EXP}[7:0] and one of the original weight exponents W0_{EXP}[7:0]-W127_{EXP}[7:0] is equal to the maximum exponent adding value MAX(EXP) minus 1 (i.e., MAX(EXP)−1), the weighted input mantissa (IN_{MAn}[7:0]) is corresponding to “01M₆M₅M₄M₃M₂M₁” that is the original input mantissa INn_{MAN}[7:0] right shifted by 1 bit. When the sum (IN_{En}+W_{En}) of one of the original input exponents IN0_{EXP}[7:0]-IN127_{EXP}[7:0] and one of the original weight exponents W0_{EXP}[7:0]-W127_{EXP}[7:0] is equal to the maximum exponent adding value MAX(EXP) minus 2 (i.e., MAX(EXP)−2), the weighted input mantissa (IN_{MAN}[7:0]) is corresponding to “001M₆M₅M₄M₃M₂” that is the original input mantissa INn_{MAN}[7:0] right shifted by 2 bit. When the sum (IN_{En}+W_{En}) of one of the original input exponents IN0_{EXP}[7:0]-IN127_{EXP}[7:0] and one of the original weight exponents W0_{EXP}[7:0]-W127_{EXP}[7:0] is equal to the maximum exponent adding value MAX(EXP) minus 3 (i.e., MAX(EXP)−3), the weighted input mantissa (IN_{MAN}[7:0]) is corresponding to “0001M₆M₅M₄M₃” that is the original input mantissa INn_{MAN}[7:0] right shifted by 3 bit. When the sum (IN_{En}+W_{En}) of one of the original input exponents IN0_{EXP}[7:0]-IN127_{EXP}[7:0] and one of the original weight exponents W0_{EXP}[7:0]-W127_{EXP}[7:0] is equal to the maximum exponent adding value MAX(EXP) minus 4 (i.e., MAX(EXP)−4), the weighted input mantissa (IN_{MAn}[7:0]) is corresponding to “00001M₆M₅M₄” that is the original input mantissa INn_{MAN}[7:0] right shifted by 4 bit. When the sum (IN_{En}+W_{En}) of one of the original input exponents IN0_{EXP}[7:0]-IN127_{EXP}[7:0] and one of the original weight exponents W0_{EXP}[7:0]-W127_{EXP}[7:0] is equal to the maximum exponent adding value MAX(EXP) minus 5 (i.e., MAX(EXP)−5), the weighted input mantissa (IN_{MAn}[7:0]) is corresponding to “000001M₆M₅” that is the original input mantissa INn_{MAN}[7:0] right shifted by 5 bit. When the sum (IN_{En}+W_{En}) of one of the original input exponents IN0_{EXP}[7:0]-IN127_{EXP}[7:0] and one of the original weight exponents W0_{EXP}[7:0]-W127_{EXP}[7:0] is equal to the maximum exponent adding value MAX(EXP) minus 6 (i.e., MAX(EXP)−6), the weighted input mantissa (I_{NMAn}[7:0]) is corresponding to “0000001M₆” that is the original input mantissa INn_{MAN}[7:0] right shifted by 6 bit. When the sum (IN_{En}+W_{En}) of one of the original input exponents IN0_{EXP}[7:0]-IN127_{EXP}[7:0] and one of the original weight exponents W0_{EXP}[7:0]-W127_{EXP}[7:0] is equal to the maximum exponent adding value MAX(EXP) minus 7 (i.e., MAX(EXP)−7), the weighted input mantissa (IN_{MAn}[7:0]) is corresponding to “00000001” that is the original input mantissa INn_{MAN}[7:0] right shifted by 7 bit. When the sum (IN_{En}+W_{En}) of one of the original input exponents IN0_{EXP}[7:0]-IN127_{EXP}[7:0] and one of the original weight exponents W0_{EXP}[7:0]-W127_{EXP}[7:0] is smaller than the maximum exponent adding value MAX(EXP) minus 7 (i.e., <MAX(EXP)−7), the weighted input mantissa (IN_{MAn}[7:0]) is corresponding to “00000000” (i.e., all 0 input) that is the original input mantissa INn_{MAN}[7:0] right shifted by 8 bit.

The global digital shift and adder circuit 600a (GDSaA) is connected to the local digital adder tree 400 and the analog-to-digital converter module 500. The global digital shift and adder circuit 600a is configured to calculate the digital partial multiply-and-accumulate value pMACVD, the analog partial multiply-and-accumulate value pMACVA and the maximum exponent adding value MAX(EXP) to generate a multiply-and-accumulate value MACV (FP32). In addition, the computing method S0 of FIG. 7 can be applied to the hybrid structure 100a for computing-in-memory applications of FIG. 8.

In one embodiment, the word line and input driver 300a is configured to generate an 8-bit maximum exponent adding value MAX(EXP). The local digital adder tree 400 is configured to generate a 24-bit digital partial multiply-and-accumulate value pMACVD. The analog-to-digital converter module 500 includes eight analog-to-digital converters (ADCs) which are configured to generate eight 4-bit analog partial multiply-and-accumulate values pMACVA. The global digital shift and adder circuit 600a is configured to calculate the 24-bit digital partial multiply-and-accumulate value pMACVD, the eight 4-bit analog partial multiply-and-accumulate values pMACVA and the 8-bit maximum exponent adding value MAX(EXP) to generate a 32-bit multiply-and-accumulate value MACV (FP32), but the present disclosure is not limited thereto.

According to the aforementioned embodiments and examples, the advantages of the present disclosure are described below.
1. The hybrid structure for computing-in-memory applications and the computing method thereof of the present disclosure can perform MAC operation of higher bits in digital domain for higher accuracy while performing MAC operation of lower bits in analog domain for better parallelism.
2. The hybrid structure for computing-in-memory applications and the computing method thereof of the present disclosure can utilize the time domain exponent computing block and the input mantissa pre-align block to shift the original input mantissas according to the exponent part of the input and the exponent part of the weight and then perform the MAC operation of the mantissa part, thereby realizing the concept of input mantissa pre-alignment and improve the problem of conventional CIM operating floating point.
3. The hybrid structure for computing-in-memory applications and the computing method thereof of the present disclosure do not lose accuracy and increase the sparsity of the weighted input mantissas, thereby reducing power consumption and enhancing floating point CIM performance.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A hybrid structure for computing-in-memory applications, which is controlled by a first word line and a second word line, and the hybrid structure for computing-in-memory applications comprising:
at least one memory cell storing a weight, wherein the at least one memory cell is controlled by the first word line and comprises a local bit line transmitting the weight; and
at least one digital-analog-hybrid local computing cell controlled by the second word line and having a plurality of input lines, a digital output line and an analog output line, wherein the input lines are configured to transmit a plurality of multi-bit input values, and the at least one digital-analog-hybrid local computing cell comprises:
at least one digital local computing cell connected to the at least one memory cell, wherein the at least one digital local computing cell receives the weight via the local bit line and is configured to generate a digital output value on the digital output line according to a higher bit of the multi-bit input values multiplied by the weight; and
at least one voltage local computing cell connected to the at least one memory cell and the at least one digital local computing cell, wherein the at least one voltage local computing cell receives the weight via the local bit line and is configured to generate an analog output value on the analog output line according to a lower bit of the multi-bit input values multiplied by the weight.

2. The hybrid structure for computing-in-memory applications of claim 1, wherein the at least one digital local computing cell comprises:
a first digital transistor connected between the at least one memory cell and the digital output line, wherein the first digital transistor is controlled by the higher bit; and
a second digital transistor connected to the first digital transistor, wherein the second digital transistor is controlled by an inverted higher bit opposite to the higher bit.

3. The hybrid structure for computing-in-memory applications of claim 1, wherein the at least one voltage local computing cell comprises:
a first analog transistor connected between the at least one memory cell and the analog output line, wherein the first analog transistor is controlled by the lower bit;
a second analog transistor connected to the first analog transistor, wherein the second analog transistor is controlled by an inverted lower bit opposite to the lower bit; and
a third analog transistor connected to the first analog transistor and the second analog transistor, wherein the third analog transistor is controlled by an enable signal.

4. The hybrid structure for computing-in-memory applications of claim 1, further comprising:
a local digital adder tree connected to the at least one digital local computing cell via the digital output line;
wherein a number of the at least one digital local computing cell is plural, the digital local computing cells are configured to generate a plurality of the digital output values on a plurality of the digital output lines according to a plurality of the higher bits of the multi-bit input values multiplied by the weight, and the local digital adder tree is configured to receive the digital output values and add the digital output values to generate a digital partial multiply-and-accumulate value.

5. The hybrid structure for computing-in-memory applications of claim 4, further comprising:
at least one analog-to-digital converter connected to the at least one voltage local computing cell via the analog output line;
wherein a number of the at least one digital-analog-hybrid local computing cell is plural, the digital-analog-hybrid local computing cells are configured to generate a plurality of the analog output values on the analog output line, an analog shared output value is formed by charge sharing according to the analog output values, and the at least one analog-to-digital converter is configured to receive the analog shared output value and convert the analog shared output value into an analog partial multiply-and-accumulate value.

6. The hybrid structure for computing-in-memory applications of claim 5, further comprising:
a global digital shift and adder circuit connected to the local digital adder tree and the at least one analog-to-digital converter, wherein the local digital adder tree is connected between the at least one digital local computing cell and the global digital shift and adder circuit, the at least one analog-to-digital converter is connected between the at least one voltage local computing cell and the global digital shift and adder circuit, and the global digital shift and adder circuit is configured to calculate the digital partial multiply-and-accumulate value and the analog partial multiply-and-accumulate value to generate a multiply-and-accumulate value.

7. The hybrid structure for computing-in-memory applications of claim 1, wherein,
a number of the at least one memory cell is plural, and the memory cells comprise a first memory cell storing a first weight, a second memory cell storing a second weight and a third memory cell storing a third weight;
a number of the at least one digital local computing cell is plural, a number of the at least one voltage local computing cell is plural, and the at least one digital-analog-hybrid local computing cell further comprises:
a first column structure connected to the first memory cell, wherein the first column structure comprises a first global bit line, a first global bit line bar, seven of the digital local computing cells and one of the voltage local computing cells;
a second column structure connected to the second memory cell, wherein the second column structure comprises a second global bit line, a second global bit line bar, six of the digital local computing cells and two of the voltage local computing cells; and
a third column structure connected to the third memory cell, wherein the third column structure comprises a third global bit line, a third global bit line bar and first eight of the digital local computing cells; and
the one of the voltage local computing cells of the first column structure is connected to the first global bit line bar, the two of the voltage local computing cells of the second column structure are connected to the second global bit line and the third global bit line, respectively, and the second column structure is connected between the first column structure and the third column structure.

8. The hybrid structure for computing-in-memory applications of claim 7, wherein,
the memory cells further comprise a fourth memory cell storing a fourth weight and a fifth memory cell storing a fifth weight;
the at least one digital-analog-hybrid local computing cell further comprises:
a fourth column structure connected to the fourth memory cell, wherein the fourth column structure comprises a fourth global bit line, a fourth global bit line bar, five of the digital local computing cells and three of the voltage local computing cells; and
a fifth column structure connected to the fifth memory cell, wherein the fifth column structure comprises a fifth global bit line, a fifth global bit line bar and second eight of the digital local computing cells; and
the three of the voltage local computing cells of the fourth column structure are connected to the fifth global bit line, the third global bit line bar and the fourth global bit line bar, respectively, and the fourth column structure is connected between the third column structure and the fifth column structure.

9. The hybrid structure for computing-in-memory applications of claim 8, wherein,
the memory cells further comprise a sixth memory cell storing a sixth weight and a seventh memory cell storing a seventh weight;
the at least one digital-analog-hybrid local computing cell further comprises:
a sixth column structure connected to the sixth memory cell, wherein the sixth column structure comprises a sixth global bit line, a sixth global bit line bar, four of the digital local computing cells and four of the voltage local computing cells; and
a seventh column structure connected to the seventh memory cell, wherein the seventh column structure comprises a seventh global bit line, a seventh global bit line bar and third eight of the digital local computing cells; and
the four of the voltage local computing cells of the sixth column structure are connected to the fifth global bit line bar, the seventh global bit line, the sixth global bit line and the sixth global bit line bar, respectively, and the sixth column structure is connected between the fifth column structure and the seventh column structure.

10. The hybrid structure for computing-in-memory applications of claim 9, wherein,
the memory cells further comprise an eighth memory cell storing an eighth weight and a ninth memory cell storing a ninth weight;
the at least one digital-analog-hybrid local computing cell further comprises:
an eighth column structure connected to the eighth memory cell, wherein the eighth column structure comprises an eighth global bit line, an eighth global bit line bar, three of the digital local computing cells and five of the voltage local computing cells; and
a ninth column structure connected to the ninth memory cell, wherein the ninth column structure comprises a ninth global bit line, a ninth global bit line bar and fourth eight of the digital local computing cells; and
the five of the voltage local computing cells of the eighth column structure are connected to the ninth global bit line, the seventh global bit line bar, the eighth global bit line bar, the eighth global bit line and the ninth global bit line bar, respectively, and the eighth column structure is connected between the seventh column structure and the ninth column structure.

11. A computing method of a hybrid structure for computing-in-memory applications, which is controlled by a first word line and a second word line, and the computing method comprising:
performing a voltage level applying step, wherein the voltage level applying step comprises applying a plurality of voltage levels to the first word line, the second word line, a plurality of input lines of at least one digital-analog-hybrid local computing cell and a weight of at least one memory cell; and
performing a digital-analog-hybrid computing step, wherein the digital-analog-hybrid computing step comprises:
performing a digital computing step, wherein the digital computing step comprises configuring at least one digital local computing cell of the at least one digital-analog-hybrid local computing cell to generate a digital output value on a digital output line according to a higher bit of a plurality of multi-bit input values multiplied by the weight; and
performing an analog computing step, wherein the analog computing step comprises configuring at least one voltage local computing cell of the at least one digital-analog-hybrid local computing cell to generate an analog output value on an analog output line according to a lower bit of the multi-bit input values multiplied by the weight.

12. The computing method of claim 11, wherein the at least one digital local computing cell comprises:
a first digital transistor connected between the at least one memory cell and the digital output line, wherein the first digital transistor is controlled by the higher bit; and
a second digital transistor connected to the first digital transistor, wherein the second digital transistor is controlled by an inverted higher bit opposite to the higher bit.

13. The computing method of claim 11, wherein the at least one voltage local computing cell comprises:
a first analog transistor connected between the at least one memory cell and the analog output line, wherein the first analog transistor is controlled by the lower bit;
a second analog transistor connected to the first analog transistor, wherein the second analog transistor is controlled by an inverted lower bit opposite to the lower bit; and
a third analog transistor connected to the first analog transistor and the second analog transistor, wherein the third analog transistor is controlled by an enable signal.

14. The computing method of claim 11, wherein the hybrid structure for computing-in-memory applications comprises:
a local digital adder tree connected to the at least one digital local computing cell via the digital output line;
wherein a number of the at least one digital local computing cell is plural, the digital local computing cells are configured to generate a plurality of the digital output values on a plurality of the digital output lines according to a plurality of the higher bits of the multi-bit input values multiplied by the weight, and the local digital adder tree is configured to receive the digital output values and add the digital output values to generate a digital partial multiply-and-accumulate value.

15. The computing method of claim 14, wherein the hybrid structure for computing-in-memory applications further comprises:
at least one analog-to-digital converter connected to the at least one voltage local computing cell via the analog output line;
wherein a number of the at least one digital-analog-hybrid local computing cell is plural, the digital-analog-hybrid local computing cells are configured to generate a plurality of the analog output values on the analog output line, an analog shared output value is formed by charge sharing according to the analog output values, and the at least one analog-to-digital converter is configured to receive the analog shared output value and convert the analog shared output value into an analog partial multiply-and-accumulate value.

16. The computing method of claim 15, wherein the hybrid structure for computing-in-memory applications further comprises:
a global digital shift and adder circuit connected to the local digital adder tree and the at least one analog-to-digital converter, wherein the local digital adder tree is connected between the at least one digital local computing cell and the global digital shift and adder circuit, the at least one analog-to-digital converter is connected between the at least one voltage local computing cell and the global digital shift and adder circuit, and the global digital shift and adder circuit is configured to calculate the digital partial multiply-and-accumulate value and the analog partial multiply-and-accumulate value to generate a multiply-and-accumulate value.

17. The computing method of claim 11, wherein,
a number of the at least one memory cell is plural, and the memory cells comprise a first memory cell storing a first weight, a second memory cell storing a second weight and a third memory cell storing a third weight;
a number of the at least one digital local computing cell is plural, a number of the at least one voltage local computing cell is plural, and the at least one digital-analog-hybrid local computing cell comprises:
a first column structure connected to the first memory cell, wherein the first column structure comprises a first global bit line, a first global bit line bar, seven of the digital local computing cells and one of the voltage local computing cells;
a second column structure connected to the second memory cell, wherein the second column structure comprises a second global bit line, a second global bit line bar, six of the digital local computing cells and two of the voltage local computing cells; and
a third column structure connected to the third memory cell, wherein the third column structure comprises a third global bit line, a third global bit line bar and first eight of the digital local computing cells; and
the one of the voltage local computing cells of the first column structure is connected to the first global bit line bar, the two of the voltage local computing cells of the second column structure are connected to the second global bit line and the third global bit line, respectively, and the second column structure is connected between the first column structure and the third column structure.

18. The computing method of claim 17, wherein,
the memory cells further comprise a fourth memory cell storing a fourth weight and a fifth memory cell storing a fifth weight;
the at least one digital-analog-hybrid local computing cell further comprises:
a fourth column structure connected to the fourth memory cell, wherein the fourth column structure comprises a fourth global bit line, a fourth global bit line bar, five of the digital local computing cells and three of the voltage local computing cells; and
a fifth column structure connected to the fifth memory cell, wherein the fifth column structure comprises a fifth global bit line, a fifth global bit line bar and second eight of the digital local computing cells; and
the three of the voltage local computing cells of the fourth column structure are connected to the fifth global bit line, the third global bit line bar and the fourth global bit line bar, respectively, and the fourth column structure is connected between the third column structure and the fifth column structure.

19. The computing method of claim 18, wherein,
the memory cells further comprise a sixth memory cell storing a sixth weight and a seventh memory cell storing a seventh weight;
the at least one digital-analog-hybrid local computing cell further comprises:
a sixth column structure connected to the sixth memory cell, wherein the sixth column structure comprises a sixth global bit line, a sixth global bit line bar, four of the digital local computing cells and four of the voltage local computing cells; and
a seventh column structure connected to the seventh memory cell, wherein the seventh column structure comprises a seventh global bit line, a seventh global bit line bar and third eight of the digital local computing cells; and
the four of the voltage local computing cells of the sixth column structure are connected to the fifth global bit line bar, the seventh global bit line, the sixth global bit line and the sixth global bit line bar, respectively, and the sixth column structure is connected between the fifth column structure and the seventh column structure.

20. The computing method of claim 19, wherein,
the memory cells further comprise an eighth memory cell storing an eighth weight and a ninth memory cell storing a ninth weight;
the at least one digital-analog-hybrid local computing cell further comprises:
an eighth column structure connected to the eighth memory cell, wherein the eighth column structure comprises an eighth global bit line, an eighth global bit line bar, three of the digital local computing cells and five of the voltage local computing cells; and
a ninth column structure connected to the ninth memory cell, wherein the ninth column structure comprises a ninth global bit line, a ninth global bit line bar and fourth eight of the digital local computing cells; and
the five of the voltage local computing cells of the eighth column structure are connected to the ninth global bit line, the seventh global bit line bar, the eighth global bit line bar, the eighth global bit line and the ninth global bit line bar, respectively, and the eighth column structure is connected between the seventh column structure and the ninth column structure.
